(19) United States
(12) Patent Application Publication
(10) Pub. No.: US 2025/0105229 A1
(43) Pub. Date: Mar. 27, 2025

(54) DISPLAY DEVICE AND METHOD OF MANUFACTURING THE SAME

(71) Applicant: Samsung Display Co., LTD., Yongin-si (KR)

(72) Inventors: Tetsuhiro TANAKA, Yongin-si (KR); Jin Seok OH, Yongin-si (KR); Chang Ha KWAK, Yongin-si (KR); Jung Yub SEO, Yongin-si (KR); Jung Hoon YOON, Yongin-si (KR); Jin Ho JEONG, Yongin-si (KR)

(73) Assignee: Samsung Display Co., LTD., Yongin-si (KR)

(21) Appl. No.: 18/633,832

(22) Filed: Apr. 12, 2024

(30) Foreign Application Priority Data
Sep. 27, 2023 (KR) 10-2023-0130923

(51) Int. Cl. H01L 25/16; H01L 25/075; H01L 27/12; H01L 33/54

(52) U.S. Cl. CPC H01L 25/167; H01L 25/0753; H10D 86/0221; H10D 86/423; H10D 86/471; H10D 86/481; H10D 86/60; H10H 20/853

(57) ABSTRACT

A display device includes a transistor including an active layer disposed on a substrate and a gate electrode disposed on the active layer, a gate insulating layer disposed between the active layer and the gate electrode, and a first insulating layer disposed on the gate electrode. The first insulating layer may include a first layer covering the active layer, the gate insulating layer, and the gate electrode and including silicon oxide, a second layer disposed on the first layer and including silicon oxynitride, and a third layer disposed on the second layer and including silicon nitride.

### CROSS-REFERENCE TO RELATED APPLICATION(S)

This application claims priority to and benefits of Korean Patent Application No. 10-2023-0130923 under 35 U.S.C. 119, filed on Sep. 27, 2023, in the Korean Intellectual Property Office, the entire contents of which are incorporated herein by reference.

### BACKGROUND

### 1. Technical Field

Embodiments relate to a display device and a method of manufacturing the display device.

### 2. Description of the Related Art

Display devices have become increasingly important with the development of multimedia. Thus, various display devices, including light-emitting display devices, have been researched and developed.

### SUMMARY

Embodiments provide a display device capable of improving the operational characteristics of transistors and a method of manufacturing the display device.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, there is provided a display device including a transistor including an active layer disposed on a substrate and a gate electrode disposed on the active layer, a gate insulating layer disposed between the active layer and the gate electrode, and a first insulating layer disposed on the gate electrode. The first insulating layer may include a first layer covering the active layer, the gate insulating layer, and the gate electrode and including silicon oxide, a second layer disposed on the first layer and including silicon oxynitride, and a third layer disposed on the second layer and including silicon nitride.

In an embodiment, a thickness of the second layer may be in a range of about 1000 Å to about 2000 Å.

In an embodiment, a nitrogen content of the second layer may be in a range of about 1 atomic % to about 10 atomic %.

In an embodiment, a thickness of the first layer may be in a range of about 1000 Å to about 2000 Å.

In an embodiment, a nitrogen content of the first layer may be less than 1 atomic %.

In an embodiment, a thickness of the third layer may be in a range of about 1000 Å to about 2000 Å.

In an embodiment, a nitrogen content of the third layer may be in a range of about 30 atomic % to about 60 atomic %.

In an embodiment, a distance between the first and third layers may be about 50 Å or greater in a region where the first insulating layer covers a side of the gate electrode.

In an embodiment, the active layer may include an oxide semiconductor.

In an embodiment, the gate insulating layer may be disposed on a portion of the active layer that overlaps the gate electrode, and expose other portions of the active layer, and the first insulating layer may directly cover the other portions of the active layer.

In an embodiment, the transistor may further include at least one of a source electrode, which is disposed on the first insulating layer and connected to a portion of the active layer, and a drain electrode, which is disposed on the first insulating layer and connected to another portion of the active layer.

In an embodiment, the transistor may further include a bottom gate electrode disposed between the substrate and the active layer.

In an embodiment, the display device may further include a passivation layer disposed on the first insulating layer and covering the transistor, a light-emitting element disposed on the passivation layer, and an encapsulation layer covering the light-emitting element.

In an embodiment, the display device may further include a capacitor electrode disposed on the first insulating layer and overlapping the gate electrode, and a second insulating layer covering the capacitor electrode.

According to an aspect of the disclosure, there is provided a display device including a transistor including an active layer disposed on a substrate and a gate electrode disposed on the active layer, a gate insulating layer disposed between the active layer and the gate electrode, and an insulating layer disposed on the gate electrode and including a first layer covering the active layer, the gate insulating layer, and the gate electrode and including silicon oxide, and a second layer disposed on the first layer and including silicon oxynitride. A thickness of the second layer may be in a range of about 1000 Å to about 2000 Å.

In an embodiment, a nitrogen content of the second layer may be in a range of about 1 atomic % to about 10 atomic %.

In an embodiment, a thickness of the first layer may be in a range of about 1000 Å to about 2000 Å.

In an embodiment, the insulating layer may further include a third layer disposed on the second layer and including silicon nitride.

According to an aspect of the disclosure, there is provided a method of manufacturing a display device, including forming an active layer on a substrate, forming a gate insulating layer and a gate electrode on the active layer, and forming an insulating layer on the gate electrode. The forming of the insulating layer may include forming a first layer covering the active layer, the gate insulating layer, and the gate electrode and including silicon oxide, on the substrate, forming a second layer including silicon oxynitride, on the first layer, and forming a third layer including silicon nitride, on the second layer.

In an embodiment, the second layer may have a thickness of about 1000 Å to about 2000 Å.

According to the aforementioned and other embodiments, a display device may include a first insulating layer disposed on a gate electrode of a transistor. In some embodiments, the first insulating layer may include a first layer covering an active layer of the transistor, a gate insulating layer, and the gate electrode of the transistor, and including silicon oxide, and a second layer disposed on the first layer and including silicon oxynitride. In some embodiments, the first insulating layer may further include a third layer disposed on the second layer and including silicon nitride.

As the active layer and the gate electrode of the transistor are sequentially covered by the first layer, the second layer, and/or the third layer of the first insulating layer, the effective channel length and operational characteristics of the transistor may be adequately or properly ensured, and at the same time, moisture penetration may be effectively prevented. Accordingly, the reliability of the transistor and the display device including the transistor may be ensured.

It should be noted that the effects of the disclosure are not limited to those described above, and other effects of the disclosure will be apparent from the following description.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment;

FIG. 2 is a schematic plan view illustrating a display panel of FIG. 1;

FIG. 3 is a schematic cross-sectional view illustrating a display panel according to an embodiment;

FIG. 4 is a schematic cross-sectional view illustrating area A1 of FIG. 3;

FIG. 5 is a schematic cross-sectional view illustrating a display panel according to an embodiment; and

FIGS. 6, 7, 8, 9, 10, 11, and 12 are schematic cross-sectional views illustrating a method of manufacturing a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction D1, the axis of the second direction D2, and the axis of the third direction D3 are not limited to three axes of a rectangular coordinate system, such as the X, Y, and Z-axes, and may be interpreted in a broader sense. For example, the axis of the first direction D1, the axis of the second direction D2, and the axis of the third direction D3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

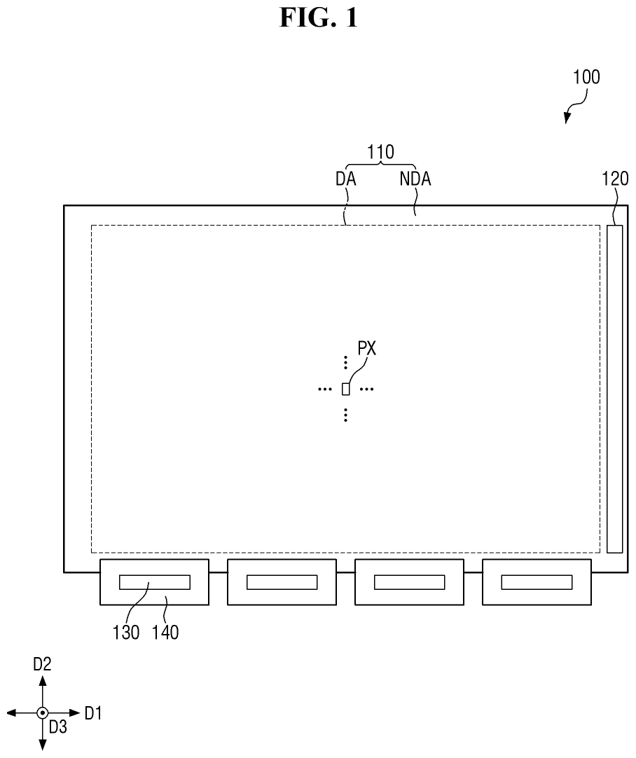

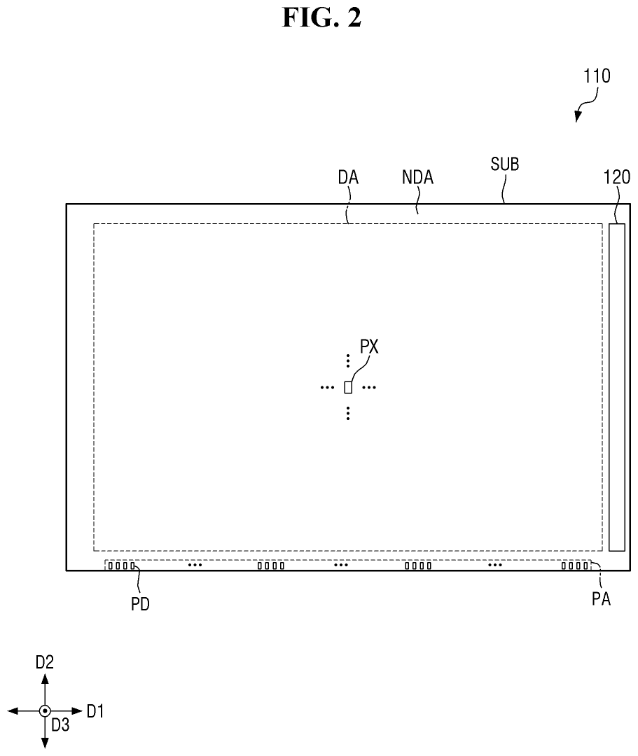

FIG. 1 is a schematic plan view illustrating a display device 100 according to an embodiment. FIG. 2 is a schematic plan view illustrating a display panel 110 of FIG. 1.

Referring to FIGS. 1 and 2, the display device 100 may be a device for displaying videos or still images and may be used as a display screen for portable electronic devices such as mobile phones, smartphones, tablet personal computers (PCs), smartwatches, watch phones, mobile communication terminals, electronic notebooks, e-book readers, portable multimedia players (PMPs), navigation devices, or ultra mobile PCs (UMPCs), as well as various other products such as televisions, laptops, monitors, advertising boards, or Internet of Things (IoT) devices. These are examples, and the display device 100 may also be adapted to other electronic devices.

In an embodiment, the display device 100 may be a light-emitting display device, such as an organic light-emitting display device including organic light-emitting diodes (OLEDs), a quantum dot light-emitting display device including quantum dot emitting layers, an inorganic light-emitting display device including inorganic semiconductors, or an ultra-small light-emitting display device using micro-light-emitting diodes or nano-light-emitting diodes (microLEDs or nanoLEDs), but embodiments are not limited thereto. For example, the display device 100 may also be a display device other than a light-emitting display device. The display device 100 will hereinafter be described as being, for example, an organic light-emitting display device.

The display device 100 may include a display panel 110, which includes pixels PX, and first and second driving units 120 and 130, which provide driving signals to the pixels PX. The display device 100 may further include additional components. For example, the display device 100 may include a power supply unit, which is for supplying power voltages to the pixels PX and the first and second driving units 120 and 130, and a timing control unit, which is for controlling the operations of the first and second driving units 120 and 130.

The display panel 110 may include a display area DA and a non-display area NDA. The display area DA may be an area for displaying an image by using the pixels PX. The non-display area NDA may be an area other than the display area DA, and no image may be displayed in the non-display area NDA. In an embodiment, the non-display area NDA may be disposed around the display area DA and may surround the display area DA.

In FIGS. 1 and 2, first, second, and third directions D1, D2, and D3 are defined. In an embodiment, the first direction D1 may be the horizontal direction of the display panel 110 (e.g., a row direction or an X-axis direction), the second direction D2 may be the vertical direction of the display panel 110 (e.g., a column direction or a Y-axis direction), and the third direction D3 may be the thickness direction of the display panel 110 (e.g., a height direction or a Z-axis direction).

In an embodiment, the display panel 110 may have a planar rectangular shape. For example, the display panel 110 may have two first sides extending in the first direction D1 and two second sides extending in the second direction D2, which intersects the first direction D1. While FIGS. 1 and 2 illustrate a display panel 110 where the first sides in the horizontal direction are longer than the second sides in the vertical direction, the shape of the display panel 110 is not limited. For example, the display panel 110 may have a shape where the second sides in the vertical direction are longer than the first sides in the horizontal direction, or where the lengths of the first and second sides are substantially the same as each other. The display panel 110 may have angled or rounded corners where the first sides and the second sides meet.

The planar shape of the display panel 110 is not limited to a rectangular shape, and various other shapes may also be applicable to the display panel 110. For example, the display panel 110 may have a square shape, a non-rectangular polygonal shape, a circular shape, an elliptical shape, an irregular shape, or another shape in a plan view.

In an embodiment, the display panel 110 may be substantially flat on a plane defined by the first and second directions D1 and D2 and may have a uniform thickness in the third direction D3. In another example, the display panel 110 may be provided in a three-dimensional (3D) shape with curves.

The display panel 110 may be provided as a rigid panel to prevent substantial deformation or as a flexible panel that is bendable, foldable, or rollable in at least one part thereof. The display panel 110 may be provided to the display device 100 in an unbent state or in a bent state in some portions thereof.

The display panel 110 may include a substrate SUB and the pixels PX, which are disposed on the substrate SUB. The pixels PX may be disposed on the substrate SUB in the display area DA.

The substrate SUB may function as a base member for manufacturing or providing the display panel 110 and may form the base surface of the display panel 110. The substrate SUB may include the display area DA and the non-display area NDA around the display area DA.

The display area DA may have various shapes. For example, the display area DA may have a square shape, a non-square polygonal shape, a circular shape, an elliptical shape, an irregular shape, or another shape. In an embodiment, the display area DA may have a shape that conforms to the shape of the display panel 110, but embodiments are not limited thereto.

In the display area DA, the pixels PX may be provided and/or arranged. For example, the display area DA may include multiple pixel areas where the pixels PX are disposed.

In an embodiment, the display device 100 may be a light-emitting display device, and each of the pixels PX may include a light-emitting element positioned in an emission region and pixel circuitry connected to the light-emitting element. Here, the term “connected” may encompass both electrical and/or physical connections. The pixel circuitry may include transistors (e.g., pixel transistors including driving transistors that generate driving currents corresponding to data signals and at least one switching transistor) and at least one capacitor (e.g., a storage capacitor).

The non-display area NDA may include a driving circuit area, which is positioned on at least one side of the display area DA, and a pad area PA where pads PD are disposed. In the non-display area NDA, at least one driving unit, the pads PD, and/or wiring may be disposed.

In the driving circuit area, at least one driving unit for driving the pixels PX or a portion of the at least one driving unit may be disposed. For example, circuit components (e.g., driving transistors and capacitors forming stage circuits of the first driving unit 120) may be disposed on the substrate SUB. In an embodiment, circuit components of the first driving unit 120 may be formed within the display panel 110 along with the pixels PX.

The pads PD may be disposed in the pad area PA. On the pad area PA, at least one circuit board 140 may be disposed and/or bonded. In an embodiment, circuit boards 140 connected to different pads PD may be disposed on the pad area PA. The pads PD may include signal pads and power pads for transmitting driving signals and power voltages for driving the pixels PX and/or the first driving unit 120 into the display panel 110.

The first and second driving units 120 and 130 may generate driving signals for controlling the operation timing and luminance of the pixels PX and may supply the driving signals to the pixels PX. For example, the first driving unit 120 may be a gate driving unit including a scan driver and may be connected to the pixels PX through respective gate lines. The first driving unit 120 may supply control signals (e.g., control signals for controlling the driving timing of the pixels PX, including scan signals and/or emission control signals) to the pixels PX. The second driving unit 130 may be a source driving circuit including source driving circuits and may be connected to the pixels PX through respective data lines. The second driving unit 130 may supply data signals to the pixels PX.

In an embodiment, at least one of the first and second driving units 120 and 130, or a portion of the first or second driving unit 120 or 130, may be integrated into the display panel 110. For example, the first driving unit 120 or a portion of the first driving unit 120 may be disposed on the substrate SUB of the display panel 110, in the non-display area NDA.

FIG. 1 illustrates an example where the first driving unit 120 is formed on a side of the display area DA (e.g., in a non-display area NDA on the right side of the display area DA), but embodiments are not limited thereto. In another example, the first driving unit 120 may be positioned only on another side of the display area DA (e.g., only in a non-display area NDA on the left side of the display area DA) or on sides (e.g., opposite sides) of the display area DA (e.g., in the non-display areas NDA on both the left and right sides of the display area DA). In another example, a portion of the first driving unit 120 may be positioned in the non-display area NDA, while another portion of the first driving unit 120 may be positioned within a non-emission region within the display area DA (e.g., in a region between the emission region of the pixel PX and the emission region of another pixel PX).

In an embodiment, another one of the first driving unit 120 and the second driving unit 130, or a portion of the other driving unit, may be disposed or formed outside the display panel 110 and may be electrically connected to the display panel 110. For example, the second driving unit 130 may be implemented using integrated circuit chips and may be disposed on the circuit boards 140, which are electrically connected to the pixels PX of the display panel 110. The second driving unit 130 may be implemented as at least one integrated circuit chip and may be mounted on the non-display area NDA of the display panel 110.

The circuit boards 140 may be connected to the display panel 110 via the pads PD. In an embodiment, the circuit boards 140 may be flexible films, such as flexible printed circuit boards (FPCB), printed circuit boards (PCBs), or chip-on-films (COFs), but embodiments are not limited thereto. In an embodiment, the circuit boards 140 may be connected to a timing control unit and/or a power supply unit, through other circuit boards or connectors.

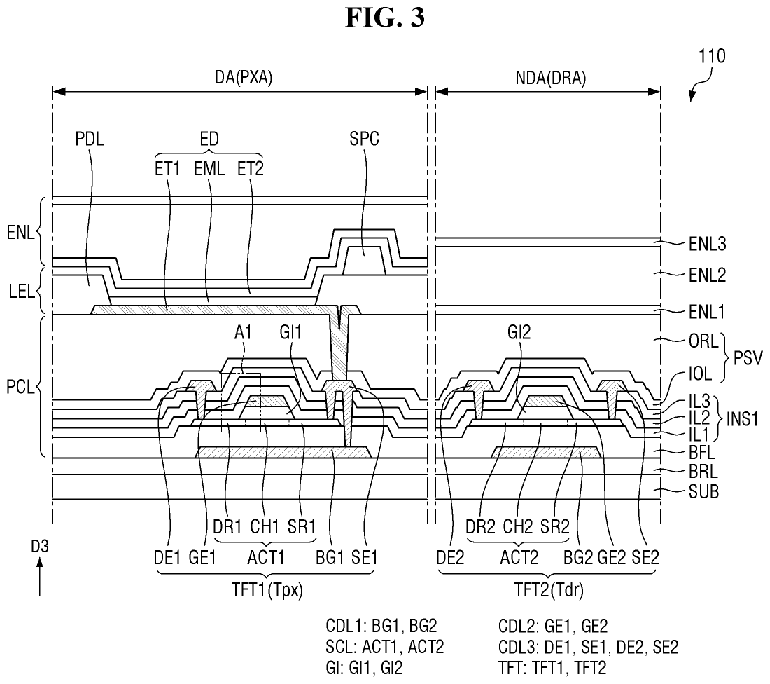

FIG. 3 is a schematic cross-sectional view illustrating the display panel 110 according to an embodiment. For example, FIG. 3 illustrates parts of the display area DA and the non-display area NDA of the display panel 110. FIG. 3 depicts a light-emitting display panel including light-emitting elements ED (e.g., OLEDs) as an example of the display panel 110.

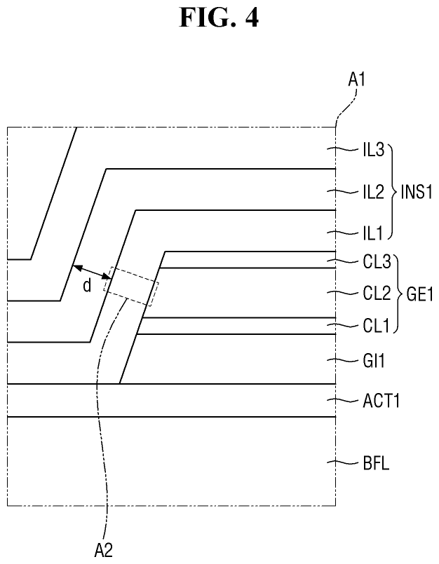

FIG. 4 is an enlarged schematic cross-sectional view illustrating area A1 of FIG. 3.

Referring to FIGS. 3 and 4 and further to FIGS. 1 and 2, the display panel 110 may include the substrate SUB (also referred to as a base layer), a panel circuit layer PCL, a light-emitting element layer LEL, and an encapsulation layer ENL. The panel circuit layer PCL, the light-emitting element layer LEL, and the encapsulation layer ENL may overlap one another on the substrate SUB. For example, the panel circuit layer PCL, the light-emitting element layer LEL, and the encapsulation layer ENL may be sequentially disposed or formed on the substrate SUB along the third direction D3, in the display area DA, but embodiments are not limited thereto. The location of the panel circuit layer PCL, the light-emitting element layer LEL, and/or the encapsulation layer ENL may vary.

In an embodiment, the display panel 110 may further include additional components provided (or formed) on top and/or bottom of the encapsulation layer ENL. For example, the display panel 110 may include at least one additional layer, such as a sensor layer (e.g., a touch sensor layer), an optical layer (e.g., a color filter layer and/or a wavelength conversion layer), and a protective layer (e.g., a protective film, an insulating layer, an upper substrate, and/or a window). Each of the sensor layer, the optical layer, and the protective layer may be provided (or formed) on an upper surface of the encapsulation layer ENL or between the light-emitting element layer LEL and the encapsulation layer ENL.

The substrate SUB may be a base member for forming the display panel 110 and may be either a rigid or flexible substrate (or film). In an embodiment, the substrate SUB may be a rigid substrate including an insulating material such as glass and may not be bendable. In another example, the substrate SUB may include polyimide or another insulating material and may be a flexible substrate that is bendable, foldable, or rollable. The type and the material of the substrate SUB may vary.

The substrate SUB may include the display area DA and the non-display area NDA. In an embodiment, the display area DA may include a pixel area PXA corresponding to the pixel PX, and the non-display area NDA may include a driving circuit area DRA. For example, the pixel area PXA where the pixel PX is disposed may be defined in the display area DA, and the driving circuit area DRA where the first driving unit 120 is disposed may be defined in the non-display area NDA.

In an embodiment, a barrier layer BRL may be provided (or formed) on the substrate SUB. For example, the display panel 110 may further include a barrier layer BRL, which is disposed between the substrate SUB and the panel circuit layer PCL. The display panel 110 may not include the barrier layer BRL, and the panel circuit layer PCL may be disposed (e.g., directly disposed) on the substrate SUB.

The barrier layer BRL may include at least one inorganic insulating layer including an inorganic insulating material (e.g., silicon nitride, silicon oxide, silicon oxynitride, titanium oxide, aluminum oxide, or another inorganic insulating material). The barrier layer BRL may protect the pixel PX from moisture that infiltrates (or permeates) through the substrate SUB. The material of the barrier layer BRL may vary.

The panel circuit layer PCL may be disposed on the substrate SUB where the barrier layer BRL is provided (or formed). The panel circuit layer PCL may include circuit components, such as a pixel transistor Tpx and a driving transistor Tdr, and wiring (e.g., signal lines and power lines). In an embodiment, the panel circuit layer PCL may further include an additional conductive pattern layer (e.g., a bridge pattern layer).

The pixel transistor Tpx may be included in the pixel circuit of the pixel PX and may be positioned in the display area DA. For example, the pixel transistor Tpx may be disposed in the pixel area PXA of the pixel PX. FIG. 3 illustrates a pixel transistor Tpx connected to a light-emitting element ED of the pixel PX, and the pixel transistor Tpx will hereinafter be referred to as a first transistor TFT1.

The driving transistor Tdr may be included in the first drive unit 120 and may be positioned in the driving circuitry area DRA. In an embodiment, the driving circuitry area DRA may be disposed in the non-display area NDA. FIG. 3 illustrates a driving transistor Tdr, which will hereinafter be referred to as a second transistor TFT2.

A transistor TFT (e.g., the first or second transistor TFT1 or TFT2) may include an active layer (e.g., a first or second active layer ACT1 or ACT2) and a gate electrode (e.g., a first or second gate electrode GE1 or GE2), which is disposed on the active layer. In an embodiment, the transistor TFT may further include at least one of a bottom gate electrode (e.g., a first or second bottom gate electrode BG1 or BG2), a source electrode (e.g., a first or second source electrode SE1 or SE2), and a drain electrode (e.g., a first or second drain electrode DE1 or DE2).

The panel circuit layer PCL may include multiple insulating layers disposed on the substrate SUB. For example, the panel circuit layer PCL may include a buffer layer BFL, a gate insulating layer GI, a first insulating layer INS1 (also referred to as an interlayer insulating layer), and a passivation layer PSV, which are sequentially disposed on the substrate SUB along the third direction D3.

In an embodiment, at least one of the insulating layers provided in the panel circuit layer PCL may be disposed in the entire display area DA and/or the entire driving circuitry area DRA. For example, the buffer layer BFL, the first insulating layer INS1, and the passivation layer PSV may be disposed in the entire display area DA and the entire driving circuitry area DRA.

In an embodiment, the gate insulating layer GI may include insulating pattern layers disposed on portions of the active layers of the first and second transistors TFT1 and TFT2, respectively. For example, the gate insulating layer GI may include a first gate insulating layer GI1, which is disposed on a portion of the first active layer ACT1 of the first transistor TFT1 and exposes other portions of the first active layer ACT1, and a second gate insulating layer GI2, which is disposed on a portion of the second active layer ACT2 of the second transistor TFT2 and exposes other portions of the second active layer ACT2, but embodiments are not limited thereto. For example, the gate insulating layer GI may be disposed in the entire display area DA and/or the entire driving circuitry area DRA.

In an embodiment, the display panel 110 may further include an additional conductive layer and/or a passivation layer. For example, the display panel 110 may include at least one conductive layer, which is provided (or formed) on the passivation layer PSV, and at least one insulating layer, which covers the at least one conductive layer. In an embodiment where the display panel 110 further includes the at least one conductive layer on the passivation layer PSV, the at least one conductive layer may include at least one wiring and/or a bridge pattern layer (e.g., a bridge pattern layer connecting the first transistor TFT1 and the light-emitting element ED).

The first transistor TFT1 may include the first active layer ACT1 (also referred to as a first active pattern layer or a first semiconductor pattern layer) and the first gate electrode GE1. In an embodiment, the first transistor TFT1 may further include the first bottom gate electrode BG1 (also referred to as a first lower electrode or a first light shielding pattern layer). The buffer layer BFL may be disposed between the first bottom gate electrode BG1 and the first active layer ACT1. The first gate insulating layer GI1 may be disposed between the first active layer ACT1 and the first gate electrode GE1.

In an embodiment, the first transistor TFT1 may include the first source electrode SE1 and the first drain electrode DE1, which are connected to different portions of the first active layer ACT1. In another example, the first transistor TFT1 may not include separate source and drain electrodes, and a first source region SR1 and/or a first drain region DR1 of the first active layer ACT1 may be connected to other circuit components, wiring, and/or conductive pattern layers to function as the source and/or drain electrodes of the first transistor TFT1.

In an embodiment, the first transistor TFT1 may be an N-type transistor. For example, the first transistor TFT1 may be an N-type oxide semiconductor.

The first bottom gate electrode BG1 may be provided in a first conductive layer CDL1 on the substrate SUB. In an embodiment, the first conductive layer CDL1 may be disposed between the substrate SUB and the buffer layer BFL. For example, the first conductive layer CDL1 may be disposed on the barrier layer BRL and may be covered by the buffer layer BFL.

The first bottom gate electrode BG1 may be disposed between the substrate SUB and the first active layer ACT1 and may overlap the first active layer ACT1. For example, the first bottom gate electrode BG1 may be disposed below the first active layer ACT1 to overlap at least a first channel region CH1. As the first bottom gate electrode BG1 is disposed below the first active layer ACT1, external light may be prevented from entering the first active layer ACT1 (e.g., the first channel region CH1), and the operational characteristics of the first transistor TFT1 may be stabilized.

The first bottom gate electrode BG1 and the first active layer ACT1 may be spaced apart from each other by the buffer layer BFL. The first bottom gate electrode BG1 may face the first gate electrode GE1 with the first active layer ACT1 interposed between the first bottom gate electrode BG1 and the first gate electrode GE1.

In an embodiment, the first transistor TFT1 may be the driving transistor of the pixel PX, and the first bottom gate electrode BG1 of the first transistor TFT1 may be connected to the first source electrode SE1. In another example, the first transistor TFT1 may be the switching transistor of the pixel PX, and the first bottom gate electrode BG1 of the first transistor TFT1 may be connected to the first gate electrode GE1. For example, the first transistor TFT1 may be a double-gate transistor with a source-sync structure or a gate-sync structure, and the first bottom gate electrode BG1 may function as a back-gate electrode for adjusting the characteristics of the first transistor TFT1.

The first active layer ACT1 may be provided in a semiconductor layer SCL on the substrate SUB. In an embodiment, the semiconductor layer SCL may be disposed on the buffer layer BFL and may be covered by the gate insulating layer GI) and the first insulating layer INS1.

The first active layer ACT1 may include the first channel region CH1 and the first source region SR1 and the first drain region DR1, which are spaced apart from each other with the first channel region CH1 interposed between the first source region SR1 and the first drain region DR1. For example, the first source region SR1 and the first drain region DR1 may be positioned on sides (e.g., opposite sides) of the first channel region CH1. The first channel region CH1 may be a region that remains undoped and maintains semiconductor properties. The first source region SR1 and the first drain region DR1 may be doped regions having a higher carrier concentration (e.g., a higher electron concentration) compared to the first channel region CH1.

The first active layer ACT1 may overlap the first bottom gate electrode BG1 and the first gate electrode GE1. For example, a portion of the first active layer ACT1 including the first channel region CH1 may overlap the first bottom gate electrode BG1 and the first gate electrode GE1.

In an embodiment, the first active layer ACT1 may include an oxide semiconductor. For example, the first active layer ACT1 may be formed of at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), and indium-tin-gallium-zinc oxide (ITGZO) or another oxide semiconductor.

In an embodiment, the first active layer ACT1 may be formed of a high-mobility oxide semiconductor (e.g., an oxide semiconductor material with a mobility of about 20 or about 30 cm²/Vs or greater. For example, the first active layer ACT1 may be formed of IGZO or ITGZO and may have a mobility of about 30 cm²/Vs or greater. Using a high-mobility oxide semiconductor for the first active layer ACT1 may ensure the conductivity of the first source region SR1 and the first drain region DR1 without an additional doping process. Furthermore, using a high-mobility oxide semiconductor for the first active layer ACT1 may provide the miniaturization of the first transistor TFT1 to a small size, possibly with an active layer width and/or length in the range of a few micrometers, while still maintaining the desired mobility for the first transistor TFT1.

The first gate insulating layer GI1 (also referred to as a first gate insulating pattern layer) may be positioned on the first active layer ACT1. The first gate insulating layer GI1 may be disposed between the first active layer ACT1 and the first gate electrode GE1.

In an embodiment, the first gate insulating layer GI1 may be disposed only on a portion of the first active layer ACT1 that overlaps the first gate electrode GE1, and may not be disposed on other portions of the first active layer ACT1. For example, the first gate insulating layer GI1 may cover the portion of the first active layer ACT1 that includes the first channel region CH1 and may expose the first source region SR1 and the first drain region DR1. In an embodiment, the first gate insulating layer GI1 may be an island-shaped insulating pattern layer having a shape and size corresponding to the first gate electrode GE1, and may be individually and/or independently formed in each transistor region where the first transistor TFT1 (e.g., a pixel transistor Tpx) is formed, but embodiments are not limited thereto. For example, the first gate insulating layer GI1 may be disposed in the entire display area DA.

As the first gate insulating layer GI1 exposes the first source region SR1 and the first drain region DR1, the first source region SR1 and the first drain region DR1 may be adequately and readily doped during the manufacture of the display panel 110. For example, during the etching of the gate insulating layer GI to expose the first source region SR1 and the first drain region DR1, oxygen vacancies may be generated in the first source region SR1 and the first drain region DR1 due to an etching gas. Consequently, the first source region SR1 and the first drain region DR1 may be appropriately doped in a subsequent process (e.g., during the formation of the first insulating layer INS1) without a separate doping process.

In an embodiment, in order to limit the carrier concentration of the first source region SR1 and the first drain region DR1 and/or the mobility of the first active layer ACT1, an oxygen supply layer may be formed between the first gate insulating layer GI1 and the first gate electrode GE1. For example, the first transistor TFT1 may be disposed between the first gate insulating layer GI and the first gate electrode GE1 and may include an oxygen supply layer including an oxide semiconductor. The first active layer ACT1 and the oxygen supply layer in the first transistor TFT1 may include the same oxide semiconductor or different oxide semiconductors.

The first gate electrode GE1 may be provided in a second conductive layer CDL2 on the substrate SUB. In an embodiment, the second conductive layer CDL2 may be disposed on the gate insulating layer GI and may be covered by the first insulating layer INS1. For example, the first gate electrode GE1 may be disposed on the first gate insulating layer GI1 and may be covered by the first insulating layer INS1.

The first gate electrode GE1 may be disposed on the first active layer ACT1 to overlap the first channel region CH1. The first gate electrode GE1 and the first active layer ACT1 may be separated and/or spaced apart from each other with the first gate insulating layer GI1 interposed between the first gate electrode GE1 and the first active layer ACT1.

The first source electrode SE1 and the first drain electrode DE1 may be provided in a third conductive layer CDL3 on the substrate SUB. In an embodiment, the third conductive layer CDL3 may be disposed on the first insulating layer INS1, which covers (e.g., entirely covers) the buffer layer BFL, the semiconductor layer SCL, the gate insulating layer GI, and the second conductive layer CDL2. The third conductive layer CDL3 may be covered by the passivation layer PSV.

The first source electrode SE1 may be connected to a portion of the first active layer ACT1. For example, the first source electrode SE1 may be connected to the first source region SR1 through at least one contact hole that penetrates the first insulating layer INS1. In a case where the first transistor TFT1 is a double-gate transistor with a source-sync structure, the first source electrode SE1 may be further connected to the first bottom gate electrode BG1. For example, the first source electrode SE1 may be connected to the first bottom gate electrode BG1 through a contact hole that penetrates the buffer layer BFL and the first insulating layer INS1.

The first drain electrode DE1 may be connected to another portion of the first active layer ACT1. For example, the first drain electrode DE1 may be connected to the first drain region DR1 through a contact hole that penetrates the first insulating layer INS1.

The second transistor TFT2 may include the second active layer ACT2 (also referred to as a second active pattern layer or a second semiconductor pattern layer) and the second gate electrode GE2. In an embodiment, the second transistor TFT2 may further include the second bottom gate electrode BG2 (also referred to as a second lower electrode or a second light shielding pattern layer). The buffer layer BFL may be disposed between the second bottom gate electrode BG2 and the second active layer ACT2. The second gate insulating layer GI2 may be disposed between the second active layer ACT2 and the second gate electrode GE2.

In an embodiment, the second transistor TFT2 may include the second source electrode SE2 and the second drain electrode DE2, which are connected to different portions of the second active layer ACT2. In another example, the second transistor TFT2 may not include separate source and drain electrodes, and a second source region SR2 and/or a second drain region DR2 of the second active layer ACT2 may be connected to other circuit components, wiring, and/or conductive pattern layers to function as the source and/or drain electrodes of the second transistor TFT2.

In an embodiment, the second transistor TFT2 may be an N-type transistor. For example, the second transistor TFT2 may be an N-type oxide semiconductor.

The second bottom gate electrode BG2 may be provided in the first conductive layer CDL1 on the substrate SUB. For example, the second bottom gate electrode BG2 may be provided in the first conductive layer CDL1 together with the first bottom gate electrode BG1.

The second bottom gate electrode BG2 may be disposed between the substrate SUB and the second active layer ACT2 and may overlap the second active layer ACT2. For example, the second bottom gate electrode BG2 may be disposed below the second active layer ACT2 to overlap at least a second channel region CH2. As the second bottom gate electrode BG2 is disposed below the second active layer ACT2, external light may be prevented from entering the second active layer ACT2 (e.g., the second channel region CH2), and the operational characteristics of the second transistor TFT2 may be stabilized.

The second bottom gate electrode BG2 and the second active layer ACT2 may be spaced apart from each other by the buffer layer BFL. The second bottom gate electrode BG2 may face (or overlap) the second gate electrode GE2 with the second active layer ACT2 interposed between the second bottom gate electrode BG2 and the second gate electrode GE2.

In an embodiment, the second transistor TFT2 may be a buffer transistor (e.g., a pull-up or pull-down transistor) or another switching transistor provided at the output terminal of the first driving unit 120, and the second bottom gate electrode BG2 may be connected to the second gate electrode GE2. For example, the second transistor TFT2 may be a double-gate transistor with a gate-sync structure, and the second bottom gate electrode BG2 may function as a back-gate electrode for adjusting the characteristics of the second transistor TFT2.

The second active layer ACT2 may be provided in the semiconductor layer SCL on the substrate SUB. For example, the second active layer ACT2 may be disposed on the buffer layer BFL and may be covered by the second gate insulating layer GI2 and the first insulating layer INS1.

The second active layer ACT2 may include the second channel region CH2 and the second source region SR2 and the second drain region DR2, which are spaced apart from each other with the second channel region CH2 interposed between the second source region SR2 and the second drain region DR2. For example, the second source region SR2 and the second drain region DR2 may be positioned on sides (e.g., opposite sides) of the second channel region CH2. The second channel region CH2 may be a region that remains undoped and maintains semiconductor properties. The second source region SR2 and the second drain region DR2 may be doped regions having a higher carrier concentration (e.g., a higher electron concentration) as compared to the second channel region CH2.

The second active layer ACT2 may overlap the second bottom gate electrode BG2 and the second gate electrode GE2. For example, a portion of the second active layer ACT2 including the second channel region CH2 may overlap the second bottom gate electrode BG2 and the second gate electrode GE2.

In an embodiment, the second active layer ACT2 may include an oxide semiconductor. For example, the second active layer ACT2 may include any one of the aforementioned oxide semiconductors for forming the first active layer ACT1 or another oxide semiconductor. In an embodiment, the first and second active layers ACT1 and ACT2 may include the same oxide semiconductor. For example, the first and second active layers ACT1 and ACT2 may be formed on the buffer layer BFL at the same time using the same oxide semiconductor. Consequently, the manufacture of the display panel 110 may be simplified, and the manufacturing efficiency of the display panel 110 may be improved.

In an embodiment, the second active layer ACT2 may be formed of a high-mobility oxide semiconductor. Using a high-mobility oxide semiconductor for the second active layer ACT2 may ensure the conductivity of the second source region SR2 and the second drain region DR2 without an additional doping process. Furthermore, using a high-mobility oxide semiconductor for the second active layer ACT2 may provide the miniaturization of the second transistor TFT2 to a small size, possibly with an active layer width and/or length in the range of a few micrometers, while still maintaining the desired mobility for the second transistor TFT2.

The second gate insulating layer GI2 (also referred to as a second gate insulating pattern layer) may be positioned on the second active layer ACT2. The second gate insulating layer GI2 may be disposed between the second active layer ACT2 and the first gate electrode GE1.

In an embodiment, the second gate insulating layer GI2 may be disposed only on a portion of the second active layer ACT2 that overlaps the first gate electrode GE1, and may not be disposed on other portions of the second active layer ACT2. For example, the second gate insulating layer GI2 may cover the portion of the second active layer ACT2 that includes the second channel region CH2 and may expose the second source region SR2 and the second drain region DR2. In an embodiment, the second gate insulating layer GI2 may be an island-shaped insulating pattern layer having a shape and size corresponding to the first gate electrode GE1, and may be individually and/or independently formed in each transistor region where the second transistor TFT2 (e.g., a driving transistor Tdr) is formed, but embodiments are not limited thereto. For example, the second gate insulating layer GI2 may be disposed in the entire driving circuit area DRA. For example, the first and second gate insulating layers GI1 and GI2 may be incorporated into a single gate insulating layer GI and may then be disposed in the entire display area DA and the entire driving circuit area DRA.

As the second gate insulating layer GI2 exposes the second source region SR2 and the second drain region DR2, the second source region SR2 and the second drain region DR2 may be adequately and readily doped during the manufacture of the display panel 110. For example, during the etching of the gate insulating layer GI to expose the second source region SR2 and the second drain region DR2, oxygen vacancies may be generated in the second source region SR2 and the second drain region DR2 due to an etching gas. Consequently, the second source region SR2 and the second drain region DR2 may be appropriately doped in a subsequent process (e.g., during the formation of the first insulating layer INS1) without a separate doping process.

In an embodiment, in order to limit the carrier concentration of the second source region SR2 and the second drain region DR2 and/or the mobility of the second active layer ACT2, an oxygen supply layer may be formed between the second gate insulating layer GI2 and the second gate electrode GE2. For example, the second transistor TFT2 may be disposed between the second gate insulating layer GI2 and the second gate electrode GE2 and may include an oxygen supply layer including an oxide semiconductor. The second active layer ACT2 and the oxygen supply layer in the second transistor TFT2 may include the same oxide semiconductor or different oxide semiconductors.

The second gate electrode GE2 may be provided in the second conductive layer CDL2. For example, the second gate electrode GE2 may be disposed on the gate insulating layer GI (e.g., on the second gate insulating layer GI2) and may be covered by a second insulating layer INS2.

The second gate electrode GE2 may be disposed on the second active layer ACT2 to overlap the second channel region CH2. The second gate electrode GE2 and the second active layer ACT2 may be separated and/or spaced apart from each other with the second gate insulating layer GI2 interposed between the second gate electrode GE2 and the second active layer ACT2.

The second source electrode SE2 and the second drain electrode DE2 may be provided in the third conductive layer CDL3. For example, the second source electrode SE2 and the second drain electrode DE2 may be disposed on the first insulating layer INS1 and may be covered by the passivation layer PSV.

The second source electrode SE2 may be connected to a portion of the second active layer ACT2. For example, the second source electrode SE2 may be connected to the second source region SR2 through a contact hole that penetrates the first insulating layer INS1.

The second drain electrode DE2 may be connected to another portion of the second active layer ACT2. For example, the second drain electrode DE2 may be connected to the second drain region DR2 through a contact hole that penetrates the first insulating layer INS1.

Transistors TFT including the first and second transistors TFT1 and TFT2 may be covered by the passivation layer PSV.

The electrodes, conductive pattern layers, and/or wirings provided in each of the conductive layers of the panel circuit layer PCL may include at least one conductive material. For example, the electrodes, conductive pattern layers, and/or wirings provided in each of the first, second, and third conductive layers CDL1, CDL2, and CDL3 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), and other metals, their alloys, or other conductive materials. In an embodiment, the electrodes, conductive pattern layers, and/or wirings disposed in the same conductive layer may be simultaneously formed of the same conductive material.

In an embodiment, the electrodes, conductive pattern layers, and/or wirings provided in each of the conductive layers of the panel circuit layer PCL may have a single-layer structure or a multi-layer structure. For example, the electrodes, conductive pattern layers, and/or wirings provided in each of the first, second, and third conductive layers CDL1, CDL2, and CDL3 may have a single-layer structure or a multi-layer structure.

For example, referring to FIG. 4, the gate electrodes (e.g., the first and second gate electrodes GE1 and GE2), conductive pattern layers, and/or wirings provided in the second conductive layer CDL2, may have a multi-layer structure including first, second, and third layers CL1, CL2, and CL3, and the first, second, and third layers CL1, CL2, and CL3 may include first, second, and third conductive materials, respectively. The first and third conductive materials may be the same as each other or different from each other, and the second conductive material may be different from the first and third conductive materials. For example, the first gate electrode GE1 and the second gate electrode GE2 may have a triple-layer structure of titanium (Ti)/aluminum (Al)/titanium (Ti), but embodiments are not limited thereto.

The passivation layer PSV may be disposed on the third conductive layer CDL3. For example, the passivation layer PSV may be disposed on the first insulating layer INS1 and may cover the third conductive layer CDL3.

In an embodiment, the passivation layer PSV may have a multi-layer structure including an inorganic insulating layer and an organic insulating layer. For example, the passivation layer PSV may include an inorganic film IOL and an organic film ORL, which are sequentially disposed on the first insulating layer INS1.

In an embodiment, each of the buffer layer BFL, the gate insulating layer GI, the first insulating layer INS1, and the inorganic film IOL may include at least one inorganic insulating layer including an inorganic insulating material (e.g., silicon nitride, silicon oxide, silicon oxynitride, titanium oxide, aluminum oxide, or another inorganic insulating material). In an embodiment, the organic film ORL may include at least one organic insulating layer including an organic insulating material (e.g., an acrylic resin, epoxy resin, phenolic resin, polyamide resin, polyimide resin, or another organic insulating material). The surface (e.g., the upper surface) of the organic film ORL may be substantially flat.

In some embodiments, the first insulating layer INS1 may be disposed on the second conductive layer CDL2 and may cover the semiconductor layer SCL, the gate insulating layer GI, and the second conductive layer CDL2. For example, the first insulating layer INS1 may cover the first and second active layers ACT1 and ACT2, which are provided in the semiconductor layer SCL, the first and second gate insulating layers GI1 and GI2, which are provided in the gate insulating layer GI, and the first and second gate electrodes GE1 and GE2, which are provided in the second conductive layer CDL2.

In some embodiments, the first insulating layer INS1 may be an at least dual insulating layer including a silicon oxide layer and a silicon oxynitride layer. For example, the first insulating layer INS1 may include a first layer IL1, which is disposed on the second conductive layer CDL2 and includes silicon oxide (SiOₓ), and a second layer IL2, which is disposed on the first layer IL1 and includes silicon oxynitride (SiOₓN_{y}). In an embodiment, the first insulating layer INS1 may further include a third layer IL3 (e.g., a silicon nitride layer), which is disposed on the second layer IL2 and includes silicon nitride (SiNₓ).

For example, the first layer IL1 of the first insulating layer INS1 may be formed of silicon and oxygen and may not substantially contain nitrogen. For example, the first layer IL1 may be formed as a silicon oxide layer, and the nitrogen content of the first layer IL1 may be less than about 1 atomic %. The first layer IL1 may cover the first and second active layers ACT1 and ACT2, the first and second gate insulating layers GI1 and GI2, and the first and second gate electrodes GE1 and GE2.

By initially covering the active layers of the transistors TFT with the first layer IL1, which is formed of silicon oxide, the amount of hydrogen infiltrating (or permeating) into the active layers of the transistors TFT during the formation of the second layer IL2 and/or the third layer IL3 including nitrogen may be controlled and/or reduced. For example, by forming the first layer IL1 to cover (e.g., directly cover) portions of the transistors TFT that are not covered by the gate insulating layer GI, for example, the first and second source regions SR1 and SR2 and the first and second drain regions DR1 and DR2, an excessively high amount of hydrogen infiltrating (or permeating) into the transistors TFT during the formation of the second layer IL2 and/or the third layer IL3 may be prevented or improved, and effective channel lengths may be adequately expanded and/or ensured for the transistors TFT. For example, in the case of forming at least some transistors TFT (e.g., the first and second transistors TFT1 and TFT2) with small-sized active layers, for example, in the range of a few micrometers to tens of micrometers in width and/or length, to manufacture a high-resolution display device 100, effective channel lengths capable of preventing or improving the occurrence of the threshold voltage roll-off phenomenon of the transistors TFT may be ensured. Accordingly, the operational characteristics of the transistors TFTs may be adequately ensured and/or enhanced, and the yield of the display device 100 may be improved.

In an embodiment, the thickness of the first layer IL1 of the first insulating layer INS1 may be in a range of about 1000 Å to about 2000 Å. By forming the first layer IL1 with a thickness of about 1000 Å or greater, a stable separation distance may be effectively ensured between the active layers (e.g., the first and second active layers ACT1 and ACT2) of the transistors TFT and the second layer IL2 and/or the third layer IL3 of the first insulating layer INS1, and an excessive infiltration (or permeation) of hydrogen into the active layers of the transistors TFT may be prevented. For example, by forming the first layer IL1 with a thickness of about 2000 Å or less, contact holes (e.g., contact holes formed in the first insulating layer INS1 to connect the active layers and source and/or drain electrodes of the transistors TFT) may be readily and stably formed.

The second layer IL2 of the first insulating layer INS1 may be formed as a silicon oxynitride layer consisting of silicon, oxygen, and nitrogen, and the nitrogen content of the second layer IL2 may be in a range of about 1 atomic % to about 10 atomic %. In an embodiment, by adjusting the nitrogen content of the second layer IL2, the film quality of the second layer IL2 may be appropriately controlled. For example, by ensuring that the second layer IL2 includes about 1 atomic % or more of nitrogen, the second layer IL2 may be formed to have a higher adhesion and a more uniform film quality compared to the first layer IL1.

By covering the first layer IL1 with the second layer IL2, which is formed of silicon oxynitride, the amount of hydrogen infiltrating (or permeating) into the active layers of the transistors TFT may be appropriately controlled and/or reduced while preventing or reducing moisture penetration through the first insulating layer INS1. For example, although voids connected to the first layer IL1 (e.g., in the form of seams) are formed on a side of each gate electrode (with a slope of, for example, less than 90 degrees), as shown in area A2 of FIG. 4, moisture penetration may be reduced, prevented, or blocked by covering the first layer IL1 with the second layer IL2, which is able to adhere more effectively than the first layer IL1. For example, by controlling the nitrogen content of the second layer IL2 to be about 10 atomic % or less, an excessive infiltration (or permeation) of hydrogen into the active layers of the transistors TFT may be prevented during the formation of the second layer IL2. In an embodiment, the nitrogen content of the second layer IL2 may be appropriately controlled or set in consideration of the film quality and processing capabilities of the second layer IL2.

In an embodiment, the thickness of the second layer IL2 of the first insulating layer INS1 may be in a range of about 1000 Å to about 2000 Å. By forming the second layer IL2 to have a thickness of about 1000 Å or greater, moisture infiltration (or permeation) may be stably prevented. For example, in case that the second layer IL2 is formed to have an overall thickness of about 1000 Å or greater, the second layer IL2 may be formed to have a thickness that stably prevents moisture infiltration (or permeation), for example, a thickness of at least about 50 Å, although the thickness of the second layer IL2 decreases on the side of each gate electrode (e.g., the first or second gate electrode GE1 or GE2). Consequently, in a region where the first insulating layer INS1 covers the side of each gate electrode, the first and third layers IL1 and IL3 of the first insulating layer INS1 may be spaced apart from each other by a distance d of about 50 Å or greater. For example, in case that the second layer IL2 is formed to have an overall thickness of about 1000 Å or greater, the second insulating layer IL2 may have a thickness of at least about 500 Å, and the first and third layers IL1 and IL3 may be spaced apart from each other by a distance d of about 500 Å or greater, even in the region where the first insulating layer INS1 covers the side of each gate electrode. Thus, moisture infiltration (or permeation) through the first insulating layer INS1 may be stably prevented. For example, by forming the second layer IL2 to have a thickness of about 2000 Å or less, contact holes may be readily and stably formed in the second layer IL2.

The third layer IL3 of the first insulating layer INS1 may consist of silicon and nitrogen and may not substantially contain oxygen. For example, the third layer IL3 may be formed as a silicon nitride layer including about 30 atomic % to about 60 atomic % of nitrogen, and the oxygen content of the third layer IL3 may be less than about 1 atomic %. For example, the third layer IL3 may contain a greater amount of nitrogen than the second layer IL2 and may have a higher adhesion and a more uniform film quality compared to the second layer IL2. By covering the second layer IL2 with the third layer IL3, moisture infiltration (or permeation) through the first insulating layer INS1 may be more effectively blocked. For example, since the third layer IL3 is spaced apart from the active layers of the transistors TFT by the first and second layers IL1 and IL2, an excessive infiltration (or permeation) of hydrogen into the active layers of the transistors TFT may be prevented or reduced during the formation of the third layer IL3.

In an embodiment, the thickness of the third layer IL3 of the first insulating layer INS1 may be in a range of about 1000 Å to about 2000 Å. By forming the third layer IL3 with a thickness of about 1000 Å or greater, the third layer IL3 may stably remain on the surface of the second layer IL2, although the third layer IL3 is partially etched to some extent in a subsequent process (e.g., a patterning process for the third conductive layer CDL3). Consequently, moisture infiltration (or permeation) may be effectively blocked. For example, by forming the third layer IL3 with a thickness of about 2000 Å or less, contact holes may be readily and stably formed in the third layer IL3. For example, by forming each of the first, second, and third layers IL1, IL2, and IL3 of the first insulating layer INS1 with a thickness of about 2000 Å or less, contact holes may be reliably formed in the first insulating layer INS1.

In an embodiment, each of the first, second, and third layers IL1, IL2, and IL3 of the first insulating layer INS1 may contain silicon, oxygen, and nitrogen in composition ratios as shown in Table 1 below. However, Table 1 shows the composition ratios of atoms included in each of the first, second, and third layers IL1, IL2, and IL3 of the first insulating layer INS1, and the composition ratios of the materials for forming the first, second, and third layers IL1, IL2, and IL3 of the first insulating layer INS1 may vary. For example, each of the first, second, and third layers IL1, IL2, and IL3 of the first insulating layer INS1 may contain silicon, oxygen, and/or nitrogen within the aforementioned ranges.

TABLE 1

| | Oxygen (O) | Silicon (Si) | Nitrogen (N) |
|---|---|---|---|
| Third Layer (SiNₓ) | 0.5 atomic % | 44.8 atomic % | 54.7 atomic % |
| Second Layer | 61.5 atomic % | 35.4 atomic % | 3.1 atomic % |
| (SiOₓN_{y}) | | | |
| First Layer (SiOₓ) | 63.2 atomic % | 36.7 atomic % | 0.1 atomic % |

The light-emitting element layer LEL may be disposed on the panel circuit layer PCL, which includes the transistors TFT, the gate insulating layer GI, the first insulating layer INS1, and the passivation layer PSV. For example, the light-emitting element layer LEL may be positioned at least in the display area DA and may be disposed on the passivation layer PSV.

The light-emitting element layer LEL may include the light-emitting element ED for the pixel PX. For example, the light-emitting element layer LEL may include a pixel-defining layer PDL (also referred to as a bank), which defines the emission region of the pixel PX, and the light-emitting element ED, which is positioned in the emission region. In an embodiment, the light-emitting element layer LEL may also include a spacer SPC, which is disposed on a portion of the pixel-defining layer PDL.

The light-emitting element ED may include a first electrode ET1, which is positioned in the emission region, and a light-emitting layer EML and a second electrode ET2, which are sequentially disposed on the first electrode ET1. The first electrode ET1 of the light-emitting element ED may be connected to at least one pixel transistor Tpx (e.g., the first transistor TFT1) included in the pixel PX.

The first electrode ET1 of the light-emitting element ED may be a single-layer electrode or a multi-layer electrode including at least one conductive material. In an embodiment, the first electrode ET1 may include a highly reflective metal material. For example, the first electrode ET1 may have a single-layer structure including a material such as molybdenum (Mo), titanium (Ti), copper (Cu), or aluminum (Al), or may have a multi-layer structure (e.g., ITO/Mg, ITO/MgF, ITO/Ag, or ITO/Ag/ITO) including a material such as ITO, IZO, ZnO, indium oxide (In₂O₃), Ag, Mg, Al, Pt, lead (Pb), Au, or Ni.

The light-emitting layer EML of the light-emitting element ED may include a polymer material or a low-molecular weight material. Light emitted from the light-emitting layer EML may contribute to the display of an image.

The second electrode ET2 of the light-emitting element ED may include a conductive material. In an embodiment, the second electrode ET2 may be a common film formed over the entire display area DA, covering the light-emitting layer EML and the pixel-defining layer PDL. In an embodiment, the second electrode ET2 may be formed of a transparent conductive material passing light therethrough, such as ITO, IZO, ZnO, or ITZO, or may be formed of a semitransparent conductive material such as Mg, Ag, or an alloy of Mg or Ag.

The pixel-defining layer PDL may have an opening corresponding to the emission region of the pixel PX and may surround the emission region. For example, the pixel-defining layer PDL may be formed to cover the edge portions of the first electrode ET1 of the light-emitting element ED and may include an opening exposing the rest of the first electrode ET1. The overlapping area of the exposed first electrode ET1 and the light-emitting layer EML may be defined as the emission region of the pixel PX. In an embodiment, the pixel-defining layer PDL may include at least one organic insulating layer.

The spacer SPC may be disposed on a portion of the pixel-defining layer PDL. The spacer SPC may include at least one organic insulating layer. The spacer SPC and the pixel-defining layer PDL may include the same material as each other or may include different materials from each other. The pixel-defining layer PDL and the spacer SPC may be sequentially formed by separate mask processes or may be formed simultaneously and/or integrally using a half-tone mask.

The encapsulation layer ENL may be disposed on the light-emitting element layer LEL. The encapsulation layer ENL may cover the light-emitting element layer LEL in the display area DA and extend into the non-display area NDA to come into contact with the panel circuit layer PCL. The encapsulation layer ENL may block the penetration of oxygen or moisture to the light-emitting element layer LEL and may mitigate any electrical and/or physical impacts on the panel circuit layer PCL and the light-emitting element layer LEL.

In an embodiment, the encapsulation layer ENL may include first, second, and third encapsulation layers ENL1, ENL2, and ENL3, which are sequentially disposed on the light-emitting element layer LEL. The first and third encapsulation layers ENL1 and ENL3 may be inorganic encapsulation layers including an inorganic material. The second encapsulation layer ENL2 may be an organic encapsulation layer including an organic material.

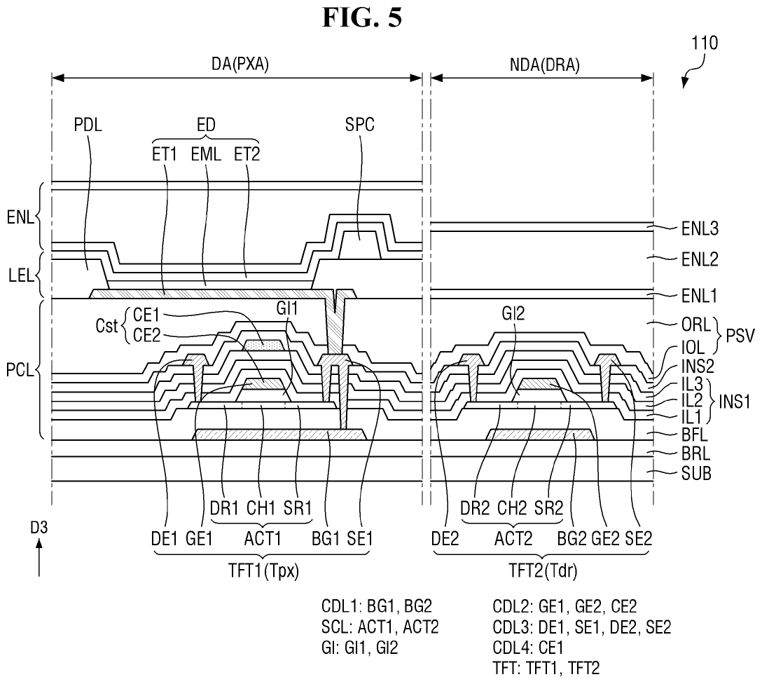

FIG. 5 is a schematic cross-sectional view illustrating the display panel 110 according to an embodiment. For example, FIG. 5 depicts portions of the display area DA and the non-display area NDA of the display panel 110 that further include a fourth conductive layer CDL4, compared to the embodiment of FIGS. 1 through 4.

Referring to FIG. 5 and further to FIGS. 1 through 4, the display panel 110 may further include the fourth conductive layer CDL4 and the second insulating layer INS2, which are disposed between the first insulating layer INS1 and the third conductive layer CDL3. For example, the fourth conductive layer CDL4 may be disposed on the first insulating layer INS1, and the second insulating layer INS2 may cover the fourth conductive layer CDL4.

The fourth conductive layer CDL4 may include at least one electrode, conductive pattern layer, and/or wiring. For example, the fourth conductive layer CDL4 may include a first capacitor electrode CE1, which forms a capacitor Cst of the pixel PX. In an embodiment, the first capacitor electrode CE1 may overlap the first gate electrode GE1, and the capacitor Cst (e.g., a storage capacitor of the pixel PX) may be formed between the first capacitor electrode CE1 and the first gate electrode GE1. For example, the first capacitor electrode CE1 of the capacitor Cst may be provided in the fourth conductive layer CDL4, and a second capacitor electrode CE2 of the capacitor Cst may be integral with the first gate electrode GE1 in the second conductive layer CDL2.

As the display panel 110 further includes the fourth conductive layer CDL4, the panel circuit layer PCL may include more conductive layers. Consequently, space for designing circuit components and/or wiring may be readily and/or adequately ensured. For example, even in a high-resolution display device 100 with reduced pixel areas PXA and/or wiring design space, sufficient space may be ensured to reliably arrange pixels PX, the first driving unit 120, and/or wiring.

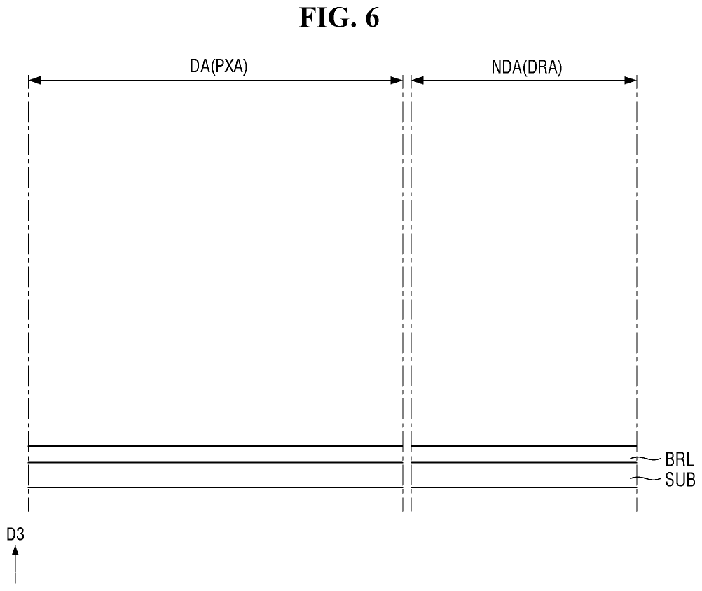

FIGS. 6 through 12 are schematic cross-sectional views illustrating a method of manufacturing the display device 100. For example, FIGS. 6 through 12 sequentially depict steps of forming the first and second transistors TFT1 and TFT2 on the substrate SUB during the manufacture of the display panel 110 of FIG. 3.

Referring to FIG. 6 and further to FIGS. 1 through 5, the substrate SUB, which has the display area DA and the non-display area NDA, may be prepared. In an embodiment, the display area DA, which is defined on the substrate SUB, may include the pixel area PXA, and the non-display area NDA may include the driving circuit area DRA.

In an embodiment, the barrier layer BRL may be formed on the substrate SUB. The barrier layer BRL may be formed in the display area DA and the non-display area NDA. The barrier layer BRL may be formed by a film formation process (e.g., a deposition process) for an insulating film using at least one of the aforementioned insulating materials (e.g., an inorganic insulating material).

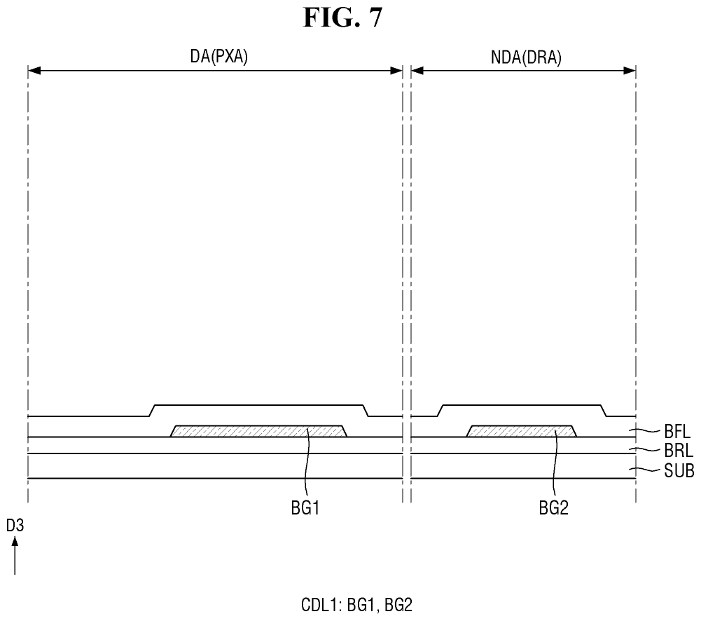

Referring to FIG. 7 and further to FIGS. 1 through 6, the first conductive layer CDL1 including the first bottom gate electrode BG1 and the second bottom gate electrode BG2 may be formed on the substrate SUB (e.g., on the barrier layer BRL). For example, the first bottom gate electrode BG1 may be formed in the pixel area PXA in the display area DA on the substrate SUB, and the second bottom gate electrode BG2 may be formed in the driving circuit area DRA on the substrate SUB. The first and second bottom gate electrodes BG1 and BG2 may be formed by a film formation process (e.g., a deposition process) and a patterning process (e.g., an etching process using a mask) for a conductive film using at least one of the aforementioned conductive materials.

Thereafter, the buffer layer BFL, which covers the first conductive layer CDL1, may be formed on the substrate SUB. The buffer layer BFL may be formed by a film formation process for an insulating film using at least one of the aforementioned insulating materials (e.g., an inorganic insulating material).

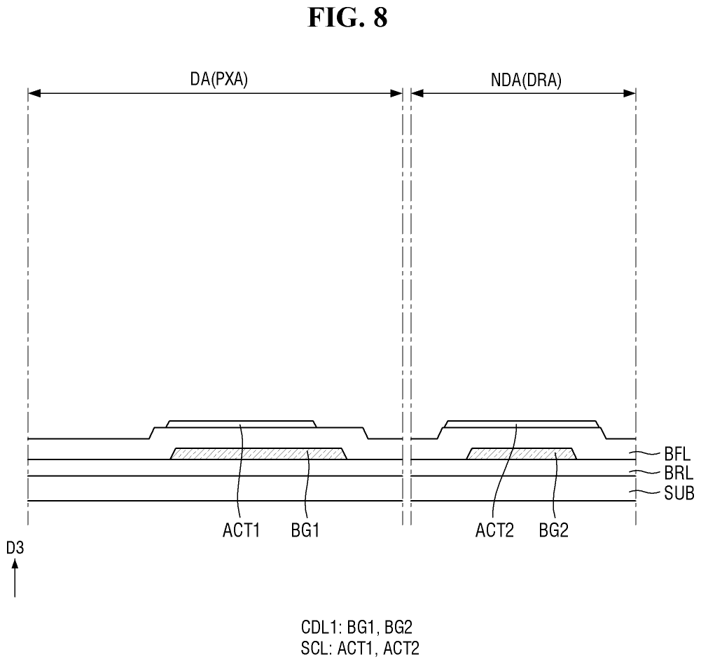

Referring to FIG. 8 and further to FIGS. 1 through 7, the semiconductor layer SCL, which includes the first and second active layers ACT1 and ACT2, may be formed on the substrate SUB (e.g., on the buffer layer BFL). For example, the first active layer ACT1 may be formed in the pixel area PXA of the display area DA on the substrate SUB, and the second active layer ACT2 may be formed in the driving circuit area DRA on the substrate SUB. The first active layer ACT1 may be formed to overlap the first bottom gate electrode BG1, and the second active layer ACT2 may be formed to overlap the second bottom gate electrode BG2.

In an embodiment, the first and second active layers ACT1 and ACT2 may be simultaneously formed of the same oxide semiconductor. For example, the first and second active layers ACT1 and ACT2 may be formed in the display area DA and the driving circuit area DRA, respectively, by a film formation process and a patterning process for a semiconductor film using at least one of the aforementioned oxide semiconductors.

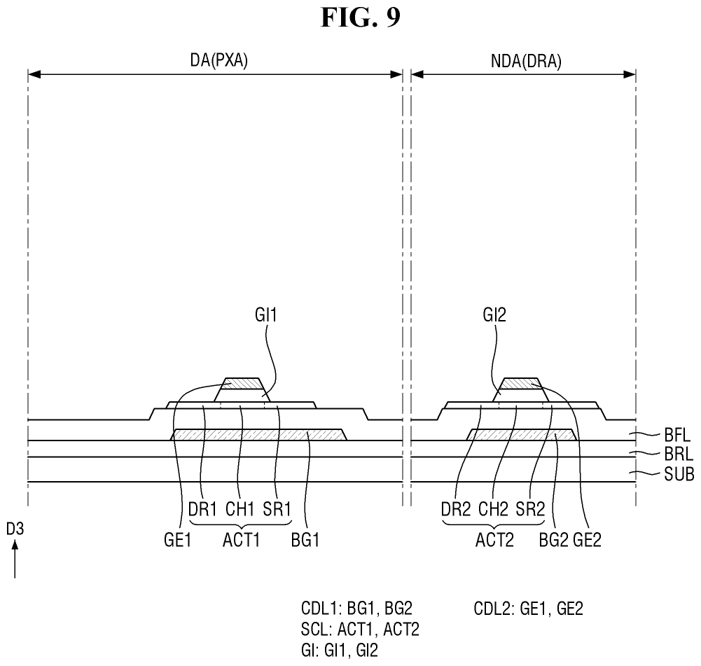

Referring to FIG. 9 and further to FIGS. 1 through 8, the gate insulating layer GI, which includes the first and second gate insulating layers GI1 and GI2, and the second conductive layer CDL2, which includes the first and second gate electrodes GE1 and GE2, may be formed on the substrate SUB where the semiconductor layer SCL is disposed. For example, an insulating film covering the semiconductor layer SCL and a conductive film covering the insulating film may be sequentially formed on the substrate SUB. In an embodiment, the insulating film and the conductive film, which are for forming the gate insulating layer GI and the second conductive layer CDL2, respectively, may be formed in the entire display area DA and the entire non-display area NDA. In an embodiment, the insulating film may be formed by a film formation process for an insulating film using at least one of the aforementioned insulating materials (e.g., an inorganic insulating material). In an embodiment, the conductive film may be formed by a film formation process for a conductive film using at least one of the aforementioned conductive materials.

Thereafter, the first and second gate insulating layers GI1 and GI2 and the first and second gate electrodes GE1 and GE2 may be formed by sequentially or simultaneously patterning the conductive film and the insulating film. In an embodiment, the conductive film may be etched and used as a mask for patterning the first and second gate electrodes GE1 and GE2, and the insulating film may be etched using the first and second gate electrodes GE1 and GE2 as a mask. For example, a mask may be placed at locations where the first and second gate electrodes GE1 and GE2 are to be formed, and the conductive film may be etched, thereby forming the first and second gate electrodes GE1 and GE2. Thereafter, the insulating film may be etched using the mask placed on the first and second gate electrodes GE1 and GE2, thereby forming the first and second gate insulating layers GI1 and GI2 below the first and second gate electrodes GE1 and GE2. As a result, the first gate insulating layer GI1 may be formed on a portion of the first active layer ACT1 that overlaps the first gate electrode GE1, and the second gate insulating layer GI2 may be formed on a portion of the second active layer ACT2 that overlaps the second gate electrode GE2.

During the formation of the first and second gate insulating layers GI1 and GI2, the properties of the first and second active layers ACT1 and ACT2 may be changed such that each of the first and second active layers ACT1 and ACT2 may have different characteristics in different areas. As a result, each of the first and second active layers ACT1 and ACT2 may be classified into multiple sections with different characteristics.

For example, in areas not overlapping the first gate electrode GE1, the bonding of the oxide in the oxide semiconductor forming the first active layer ACT1 may break, causing oxygen to detach, and oxygen vacancies may occur. Consequently, the first active layer ACT1 may be divided into multiple regions having different characteristics (e.g., the first channel region CH1, the first drain region DR1, and the first source region SR1). In an embodiment, oxygen vacancies may mainly occur in portions (e.g., the first drain region DR1 and the first source region SR1) of the first active layer ACT1 that does not overlap the first gate electrode GE1, and may extend even to a portion of the first active layer ACT1 that overlaps the first gate electrode GE1.

Similarly, in areas not overlapping the second gate electrode GE2, oxygen vacancies may occur in the oxide semiconductor forming the second active layer ACT2. Consequently, the second active layer ACT2 may be divided into multiple regions with different characteristics (e.g., the second channel region CH2, the second drain region DR2, and the second source region SR2). In an embodiment, oxygen vacancies may mainly occur in portions (e.g., the second drain region DR2 and the second source region SR2) of the second active layer ACT2 that do not overlap the second gate electrode GE2 and may extend even to a portion of the second active layer ACT2 that overlaps the second gate electrode GE2.

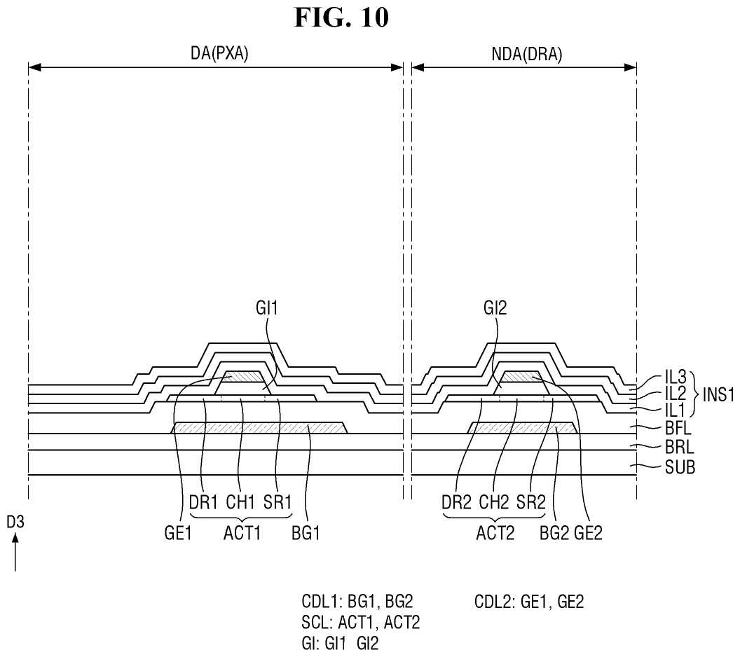

Referring to FIG. 10 and further to FIGS. 1 through 9, the first insulating layer INS1 may be formed on the substrate SUB where the semiconductor layer SCL, the gate insulating layer GI, and the second conductive layer CDL2 are disposed. For example, the first insulating layer INS1 may be formed on the second conductive layer CDL2 to cover the first and second active layers ACT1 and ACT2, the first and second gate insulating layers GI1 and GI2, and the first and second gate electrodes GE1 and GE2. The first insulating layer INS1 may be formed in the entire display area DA and the entire non-display area NDA (e.g., the driving circuit area DRA).

The first insulating layer INS1 may be formed by a film formation process for an insulating film using at least one of the aforementioned insulating materials (e.g., an inorganic insulating material). The formation of the first insulating layer INS1 may include sequentially forming the first layer IL1 (e.g., a silicon oxide layer), the second layer IL2 (e.g., a silicon nitride layer), and the third layer IL3 (e.g., a silicon carbide layer).

For example, the first insulating layer INS1 may be formed by depositing silicon oxide on the substrate SUB where the barrier layer BRL, the first conductive layer CDL1, the buffer layer BFL, the semiconductor layer SCL, the gate insulating layer GI, and/or the second conductive layer CDL2 are disposed. The first layer IL1 of the first insulating layer INS1 may be formed to cover the first and second active layers ACT1 and ACT2, the first and second gate insulating layers GI1 and GI2, and the first and second gate electrodes GE1 and GE2. In an embodiment, the first layer IL1 may be formed to have a thickness of about 1000 Å to about 2000 Å.

Thereafter, the second layer IL2 of the first insulating layer INS1 may be formed by depositing silicon nitride on the first layer IL1. In an embodiment, the second layer IL2 may be formed to cover (e.g., entirely cover) the first layer IL1 and may have a thickness of about 1000 Å to about 2000 Å.

Thereafter, the third layer IL3 of the first insulating layer INS1 may be formed by depositing silicon carbide on the second layer IL2. In an embodiment, the third layer IL3 may be formed to cover (e.g., entirely cover) the second layer IL2 and may have a thickness of about 1000 Å to 2000 Å.

During the formation of the first insulating layer INS1, hydrogen may be introduced (or permeated) into the first and second active layers ACT1 and ACT2. For example, during the formation of the second and third layers IL2 and IL3 of the first insulating layer INS1, hydrogen may be introduced (or permeated) into the first and second active layers ACT1 and ACT2. As a result, portions of the first and second active layers ACT1 and ACT2 around areas previously including a high concentration of oxygen vacancies may be doped (e.g., N-type doped). For example, the first drain region DR1, the first source region SR1, the second drain region DR2, and the second source region SR2 may be doped.

In an embodiment, by forming the second and third layers IL2 and IL3 of the first insulating layer INS1 on the first layer IL1 of the first insulating layer INS1, which covers the first and second active layers ACT1 and ACT2, an excessive infiltration (or permeation) of hydrogen into the first and second active layers ACT1 and ACT2 may be controlled or reduced. Consequently, the excessive expansion of the first drain region DR1, the first source region SR1, the second drain region DR2, and the second source region SR2 may be prevented, and the effective channel lengths of the first channel region CH1 and the second channel region CH2 may be appropriately ensured.

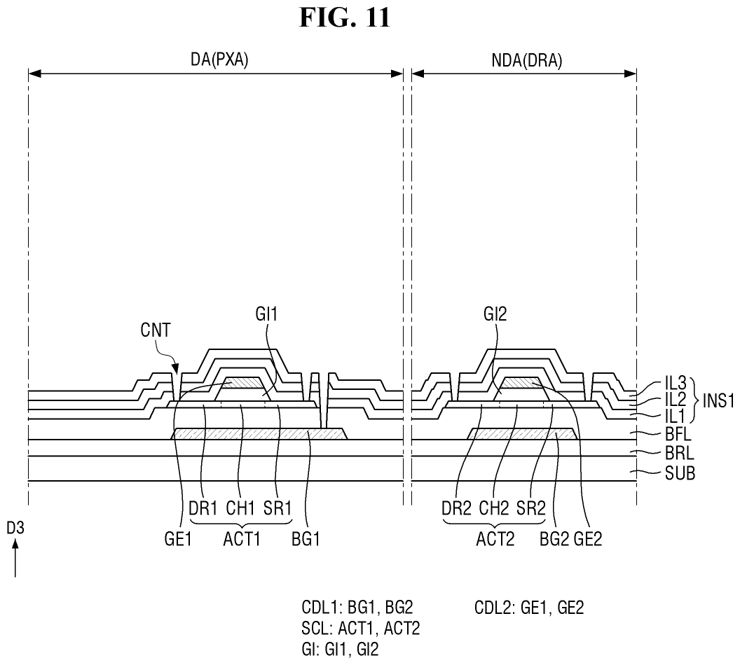

Referring to FIG. 11 and further to FIGS. 1 through 10, contact holes CNT exposing portions of the first and second active layers ACT1 and ACT2 may be formed in the first insulating layer INS1. For example, the first insulating layer INS1 may be etched to expose portions of the first drain region DR1, the first source region SR1, the second drain region DR2, and the second source region SR2. In an embodiment, by forming each layer of the first insulating layer INS1 having a thickness of about 2000 Å or less, the contact holes CNT may be readily and/or stably formed in the first insulating layer INS1. In an embodiment, in case that the first bottom gate electrode BG1 is connected to the first source electrode SE1, a contact hole CNT exposing a portion of the first bottom gate electrode BG1 in the first insulating layer INS1 and the buffer layer BFL may be formed. In FIG. 11, only one contact hole formed in the first insulating layer INS1 and/or the buffer layer BFL is referred to by “CNT.”

In an embodiment, in case that the display panel 110 further includes the fourth conductive layer CDL4 and the second insulating layer INS2, as illustrated in FIG. 5, the fourth conductive layer CDL4 and the second insulating layer INS2 may be sequentially formed before the formation of the contact holes CNT. For example, the fourth conductive layer CDL4 may be formed by forming a conductive film on the first insulating layer INS1 and patterning the conductive film, and the second insulating layer INS2 may be formed on the fourth conductive layer CDL4. Thereafter, the contact holes CNT may be formed in the first and second insulating layers INS1 and INS2.

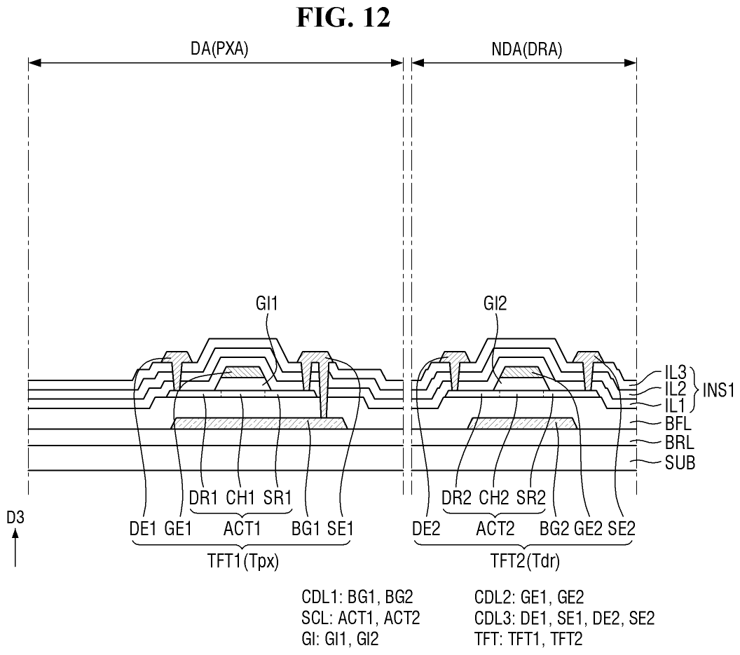

Referring to FIG. 12 and further to FIGS. 1 through 11, the third conductive layer CDL3, which includes the first source electrode SE1, the first drain electrode DE1, the second source electrode SE2, and the second drain electrode DE2, may be formed on the first insulating layer INS1. In an embodiment, at least one of the first source electrode SE1, the first drain electrode DE1, the second source electrode SE2, and the second drain electrode DE2 may not be formed, in case that at least one of the first source region SR1, the first drain region DR1, the second source region SR2, and the second drain region DR2 replaces at least one of the first source electrode SE1, the first drain electrode DE1, the second source electrode SE2, and the second drain electrode DE2.

The first source electrode SE1 may be formed to be connected to the first source region SR1, and the first drain electrode DE1 may be formed to be connected to the first drain region DR1. In an embodiment, the first source electrode SE1 may also be formed to be connected to the first bottom gate electrode BG1. The second source electrode SE2 may be formed to be connected to the second source region SR2, and the second drain electrode DE2 may be formed to be connected to the second drain region DR2.

In this manner, transistors TFT, including the first and second transistors TFT1 and TFT2, may be formed in both the display area DA and the driving circuit area DRA. In an embodiment, components provided in the same conductive layer or the same semiconductor layer within the display panel 110 may be fabricated simultaneously.

After the formation of the transistors TFT, the passivation layer PSV, as illustrated in FIG. 3, may be formed. The passivation layer PSV may cover the transistors TFT. Thus, the panel circuit layer PCL of the display panel 110 may be formed.

In an embodiment, in case that the display panel 110 includes the light-emitting element layer LEL and the encapsulation layer ENL, which are disposed on the panel circuit layer PCL, the light-emitting element layer LEL and the encapsulation layer ENL may be sequentially formed on the panel circuit layer PCL. In this manner, the display panel 110 and the display device 100 including the display panel 110 may be manufactured.

In concluding the detailed description, those skilled in the art will appreciate that many variations and modifications may be made to the embodiments without substantially departing from the principles of the invention. Therefore, the disclosed embodiments of the invention are used in a generic and descriptive sense only and not for purposes of limitation.

What is claimed is:

1. A display device comprising:
a transistor including an active layer disposed on a substrate and a gate electrode disposed on the active layer;
a gate insulating layer disposed between the active layer and the gate electrode; and
a first insulating layer disposed on the gate electrode,
wherein the first insulating layer includes:
a first layer covering the active layer, the gate insulating layer, and the gate electrode, the first layer including silicon oxide,
a second layer disposed on the first layer and including silicon oxynitride, and
a third layer disposed on the second layer and including silicon nitride.

2. The display device of claim 1, wherein a thickness of the second layer is in a range of about 1000 Å to about 2000 Å.

3. The display device of claim 1, wherein a nitrogen content of the second layer is in a range of about 1 atomic % to about 10 atomic %.

4. The display device of claim 1, wherein a thickness of the first layer is in a range of about 1000 Å to about 2000 Å.

5. The display device of claim 1, wherein a nitrogen content of the first layer is less than about 1 atomic %.

6. The display device of claim 1, wherein a thickness of the third layer is in a range of about 1000 Å to about 2000 Å.

7. The display device of claim 1, wherein a nitrogen content of the third layer is in a range of about 30 atomic % to about 60 atomic %.

8. The display device of claim 1, wherein a distance between the first and third layers is about 50 Å or greater in a region where the first insulating layer covers a side of the gate electrode.

9. The display device of claim 1, wherein the active layer includes an oxide semiconductor.

10. The display device of claim 1, wherein
the gate insulating layer is disposed on a portion of the active layer that overlaps the gate electrode, and exposes other portions of the active layer, and
the first insulating layer directly covers the other portions of the active layer.

11. The display device of claim 1, wherein the transistor further includes at least one of a source electrode, which is disposed on the first insulating layer and connected to a portion of the active layer, and a drain electrode, which is disposed on the first insulating layer and connected to another portion of the active layer.

12. The display device of claim 1, wherein the transistor further includes a bottom gate electrode disposed between the substrate and the active layer.

13. The display device of claim 1, further comprising:
a passivation layer disposed on the first insulating layer and covering the transistor;
a light-emitting element disposed on the passivation layer; and
an encapsulation layer covering the light-emitting element.

14. The display device of claim 1, further comprising:
a capacitor electrode disposed on the first insulating layer and overlapping the gate electrode; and
a second insulating layer covering the capacitor electrode.

15. A display device comprising:
a transistor including an active layer disposed on a substrate and a gate electrode disposed on the active layer;
a gate insulating layer disposed between the active layer and the gate electrode; and
an insulating layer disposed on the gate electrode and including:
a first layer covering the active layer, the gate insulating layer, and the gate electrode, the first layer including silicon oxide, and
a second layer disposed on the first layer and including silicon oxynitride, wherein a thickness of the second layer is in a range of about 1000 Å to about 2000 Å.

16. The display device of claim 15, wherein a nitrogen content of the second layer is in a range of about 1 atomic % to about 10 atomic %.

17. The display device of claim 15, wherein a thickness of the first layer is in a range of about 1000 Å to about 2000 Å.

18. The display device of claim 15, wherein the insulating layer further includes a third layer disposed on the second layer and including silicon nitride.

19. A method of manufacturing a display device, the method comprising:
forming an active layer on a substrate;
forming a gate insulating layer and a gate electrode on the active layer; and
forming an insulating layer on the gate electrode,
wherein the forming of the insulating layer comprises:
forming a first layer on the substrate, the first layer covering the active layer, the gate insulating layer, and the gate electrode and including silicon oxide,
forming a second layer on the first layer, the second layer including silicon oxynitride, and
forming a third layer on the second layer, the third layer including silicon nitride.

20. The method of claim 19, wherein the second layer has a thickness of about 1000 Å to about 2000 Å.
